(19) United States
(12) Patent Application Publication
(10) Pub. No.: US 2014/0063925 A1
(43) Pub. Date: Mar. 6, 2014

(54) PARALLEL PROGRAMMING MULTIPLE PHASE CHANGE MEMORY CELLS

(71) Applicants: Daniel J. Friedman, Sleepy Hollow, NY (US); Seongwon Kim, Old Tappan, NJ (US); Yong Liu, Rye, NY (US); Bipin Rajendran, White Plains, NY (US)

(72) Inventors: Daniel J. Friedman, Sleepy Hollow, NY (US); Seongwon Kim, Old Tappan, NJ (US); Yong Liu, Rye, NY (US); Bipin Rajendran, White Plains, NY (US)

(73) Assignee: International Business Machines Corporation, Armonk, NY (US)

(21) Appl. No.: 13/434,739

(22) Filed: Mar. 29, 2012

(51) Int. Cl. G11C 13/00

(52) U.S. Cl. CPC G11C 13/0069
USPC 365/163

(57) ABSTRACT

Embodiments of the present invention provide a device comprising a plurality of phase change memory cells, a word line, and a plurality of bit lines. Each phase change memory cell is coupled to a corresponding transistor. Each transistor is coupled to the word line. Each bit line is coupled to a phase change memory cell of the device. The device further comprises a programming circuit configured to program at least one phase change memory cell to the SET state by selectively applying a two-stage waveform to the word line and the bit lines of the device. In a first stage, a first predetermined low voltage and a first predetermined high voltage are applied at the word line and the bit lines, respectively. In a second stage, a second predetermined high voltage and a predetermined voltage with decreasing amplitude are applied at the word line and the bit lines, respectively.

This invention was made with Government support under HR0011-09-C-0002 awarded by Defense Advanced Research Projects Agency (DARPA). The Government has certain rights in this invention.

### BACKGROUND

The present invention relates to phase change memory cells, and in particular, parallel programming multiple phase change memory cells.

A phase change memory (PCM) cell is a type of non-volatile computer memory comprising a phase change material such as chalcogenide alloy. The phase change material can transition between an ordered crystalline state and a disordered amorphous state when heat in the form of an electrical pulse is applied. The phase change material transitions to the amorphous state when it is heated to a temperature greater than the melting point of the phase change material and then rapidly cooled down. The phase change material transitions to the crystalline state when it is heated to a temperature lower than the melting point of the phase change material and then gradually cooled down. In the amorphous state, the phase change material provides the PCM cell with a high level of resistivity. In the crystalline state, the phase change material provides the PCM cell with a low level of resistivity. The amorphous state and the crystalline state are generally referred to as the RESET state and the SET state, respectively. A PCM cell can be programmed to the SET state or the RESET state.

### BRIEF SUMMARY

Embodiments of the present invention provide a device comprising a plurality of phase change memory cells, a word line, and a plurality of bit lines. Each phase change memory cell is coupled to a corresponding transistor. Each transistor is coupled to the word line. Each bit line is coupled to a phase change memory cell of the device. The device further comprises a programming circuit configured to program at least one phase change memory cell to the SET state by selectively applying a two-stage waveform to the word line and the bit lines of the device. In a first stage, a first predetermined low voltage and a first predetermined high voltage are applied at the word line and the bit lines, respectively. In a second stage, a second predetermined high voltage and a predetermined voltage with decreasing amplitude are applied at the word line and the bit lines, respectively.

In another embodiment, the present invention provides a method for programming phase change memory cells of a memory device. The method comprises programming at least one phase change memory cell to a SET state by selectively applying a two-stage waveform to a word line and bit lines of the memory device.

In yet another embodiment, the present invention provides a non-transitory computer-useable storage medium for programming phase change memory cells of a memory device. The computer-useable storage medium has a computer-readable program, wherein the program upon being processed on a computer causes the computer to implement the steps of programming at least one phase change memory cell to a SET state by selectively applying a two-stage waveform to a word line and bit lines of the memory device.

These and other features, aspects and advantages of the present invention will become understood with reference to the following description, appended claims and accompanying figures.

### BRIEF DESCRIPTION OF THE SEVERAL VIEWS OF THE DRAWINGS

FIG. 1 shows a circuit diagram of a semiconductor memory device;

FIG. 2 shows an example PCM cell in the amorphous state;

FIG. 3 shows an example PCM cell in the crystalline state;

FIG. 4 shows a graph illustrating the temperature of a phase change material of a PCM cell with respect to time;

FIG. 5 shows waveforms of a word line and a bit line of a memory device during a SET operation;

FIG. 6 shows current-voltage (I-V) curves for an example PCM cell programmed by applying voltage;

FIG. 7 shows current-voltage (I-V) curves for an example PCM cell programmed by applying current;

FIG. 8A shows a semiconductor memory device, in accordance with an embodiment of the invention;

FIG. 8B shows an exploded view of a memory array of a semiconductor memory device, in accordance with an embodiment of the invention;

FIG. 9 shows a waveform of a word line of a memory device during a SET operation, in accordance with an embodiment of the invention;

FIG. 10 shows waveforms of a bit line of a memory device during RESET and SET operations, in accordance with an embodiment of the invention;

FIG. 11 shows example waveforms of a word line, a bit line, some PCM cells, and some access transistors of a memory device during a SET operation, in accordance with an embodiment of the invention;

FIG. 12 is a flowchart of an example process for reliably parallel writing PCM cells of a memory device to the SET state, in accordance with an embodiment of the invention; and

FIG. 13 is a high level block diagram showing an information processing system useful for implementing one embodiment of the present invention.

### DETAILED DESCRIPTION

The present invention relates to phase change memory cells, and in particular, parallel programming multiple phase change memory cells. Embodiments of the present invention provide a device comprising a plurality of phase change memory cells, a word line, and a plurality of bit lines. Each phase change memory cell is coupled to a corresponding transistor. Each transistor is coupled to the word line. Each bit line is coupled to a phase change memory cell of the device. The device further comprises a programming circuit configured to program at least one phase change memory cell to the SET state by selectively applying a two-stage waveform to the word line and the bit lines of the device. In a first stage, a first predetermined low voltage and a first predetermined high voltage are applied at the word line and the bit lines, respectively. In a second stage, a second predetermined high voltage and a predetermined voltage with decreasing amplitude are applied at the word line and the bit lines, respectively.

The first predetermined low voltage applied at the word line partially turns on the transistor of each phase change memory cell, such that current flowing through said phase change memory cell is limited. The first predetermined high voltage applied at the bit line of each phase change memory cell exceeds a threshold voltage of said phase change memory cell.

The second predetermined high voltage applied at the word line fully turns on the transistor of each phase change memory cell. The first predetermined voltage with decreasing amplitude applied at the bit line of each phase change memory cell causes an amorphous volume in said phase change memory cell to anneal.

In another embodiment, the present invention provides a method for programming phase change memory cells of a memory device. The method comprises programming at least one phase change memory cell to a SET state by selectively applying a two-stage waveform to a word line and bit lines of the memory device.

In yet another embodiment, the present invention provides a non-transitory computer-useable storage medium for programming phase change memory cells of a memory device. The computer-useable storage medium has a computer-readable program, wherein the program upon being processed on a computer causes the computer to implement the steps of programming at least one phase change memory cell to a SET state by selectively applying a two-stage waveform to a word line and bit lines of the memory device.

Phase change memory cells are used in a variety of applications, including neuromorphic and synaptronic computation, also referred to as artificial neural networks. Neuromorphic and synaptronic computation are computational systems that permit electronic systems to essentially function in a manner analogous to that of biological brains. Neuromorphic and synaptronic computation do not generally utilize the traditional digital model of manipulating 0 s and 1 s. Instead, neuromorphic and synaptronic computation create connections between processing elements that are roughly functionally equivalent to neurons of a biological brain. Neuromorphic and synaptronic computation may comprise various electronic circuits that are modeled on biological neurons. In biological systems, the point of contact between an axon of a neural module and a dendrite on another neuron is called a synapse. Phase change memory cells can be used to represent synapses.

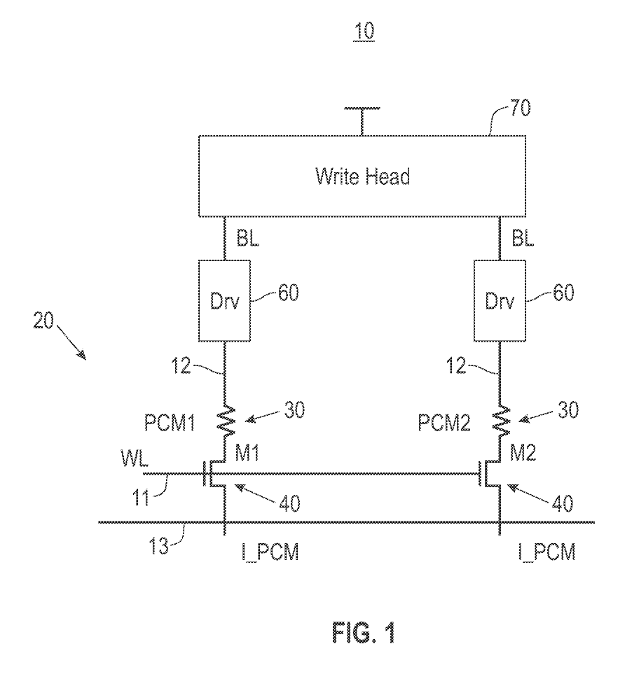

FIG. 1 shows a circuit diagram of a semiconductor memory device 10. The memory device 10 comprises a memory array 20 including a plurality of phase change memory (PCM) cells 30 such as PCM1 and PCM2. The memory device 10 further comprises a select or word line (WL) 11, a plurality of sense or bit lines (BL) 12, and a reference voltage 13.

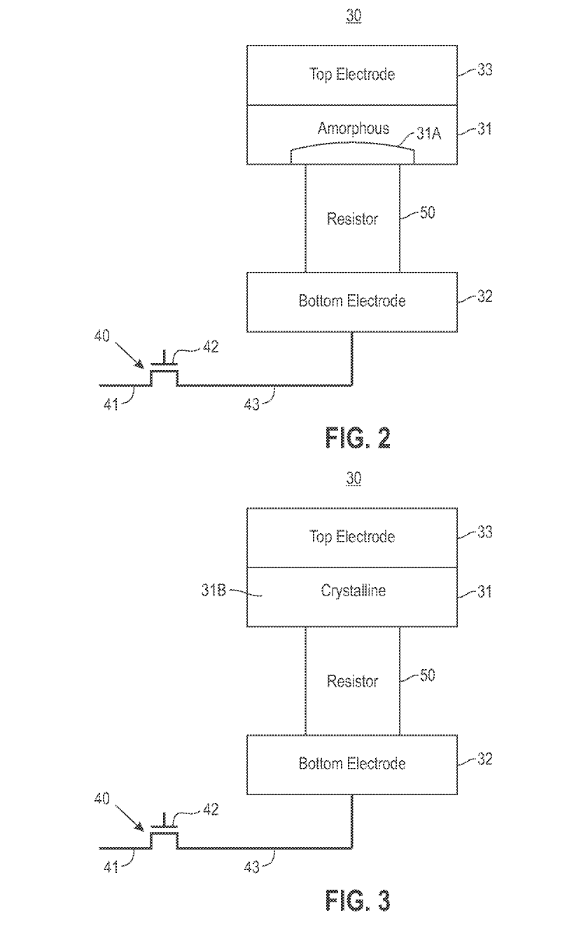

Each PCM cell 30 comprises a phase change material 31 (FIG. 2) positioned between a bottom electrode 32 (FIG. 2) and a top electrode 33 (FIG. 2). A resistance variable element (“resistor”) 50 interconnects the phase change material 31 to the bottom electrode 32. The PCM cell 30 can be programmed to switch between different levels of resistivity to represent a bit. Specifically, each PCM cell 30 can be programmed to switch between a RESET state and a SET state. In the SET state, the phase change material 31 of the PCM cell 30 is in the ordered crystalline state and has lower resistivity (e.g., 10K ohm).

Each PCM cell 30 has a corresponding access transistor 40. For each PCM cell 30, the corresponding access transistor 40 can be turned on to supply an electric current to said PCM cell 30 and switch the phase change material 31 of said PCM cell 30 between the amorphous state and the crystalline state. For example, as shown in FIG. 1, PCM1includes a transistor 40 labeled as M1, and PCM2includes a transistor 40 labeled as M2. In one embodiment, each transistor 40 is a metal oxide semiconductor field effect transistor (FET). In another embodiment, each transistor 40 is another type of access device such as a bipolar junction transistor (BJT). Each transistor 40 includes a source 41 (FIG. 2), a gate 42 (FIG. 2), and a drain 43 (FIG. 2). The gate 42 of each transistor 40 is coupled the word line 11. The source 41 of each transistor 40 is coupled to the reference voltage 13. The drain 43 of each transistor 40 is coupled to the bottom electrode 32 of the corresponding PCM cell 30. The top electrode 33 is coupled to a corresponding bit line 12 of the memory device 10. As such, each bit line 12 of the memory device 10 is coupled to a PCM cell 30 of the memory array 20.

The word line 11 controls when the PCM cells 30 are programmed. The word line 11 is activated or deactivated by increasing or decreasing the voltage on it, respectively. To activate the word line 11, the voltage of the word line 11 is set to a high voltage equal to a positive supply voltage V_{DD} (e.g., 2.5 V). To deactivate the word line 11, the voltage of the word line 11 is set to a low voltage equal to a voltage complimentary to the positive supply voltage V_{DD} (e.g., ground).

The word line 11 controls the access transistors 40. The access transistors 40 will open or close simultaneously when the voltage of the word line 11 is raised or lowered, respectively. Each transistor 40 has a threshold voltage Vₜₕ which is the gate voltage that allows the flow of electrons through the gate-source junction. If the gate voltage is below the threshold voltage Vₜₕ, the transistor 40 is turned off and generally there is no current from the drain to the source of the transistor. If the gate voltage is above the threshold voltage Vₜₕ, the transistor 40 is turned on and current can flow from drain to the source.

Each access transistor 40 controls whether the corresponding resistor 50 should be connected to the corresponding bit line. For each PCM cell 30, the transistor 40 of said PCM cell 30 may be turned on or off to access said PCM cell 30 and perform operations such as writing (i.e., programming) data to and/or reading data from the corresponding resistance variable element 50. To write data to and/or read data from the PCM cells 30, voltage and/or current signals are applied to the word line 11 and the bit lines 12. For example, to write data to and/or read data from the PCM1, the transistor M1 is turned on to allow a current to pass through the resistance variable element 50 of the PCM1.

Also shown in FIG. 1, the memory device 10 further comprises a plurality of BL drivers 60 (i.e., sense amplifiers) and a write head 70. Each BL driver 60 is coupled to a corresponding bit line 12. Each BL driver 60 is configured to write data to, or read data from, a PCM cell 30 that the corresponding bit line 12 is coupled to. The write head 70 is configured to write data to a disk.

Threshold switching is the transition from a high resistivity state to a low resistivity state. Threshold switching controls the operating voltage and speed of the PCM cells 30. Threshold switching results in an energy increase in electrons that in turn leads to an enhancement of conductivity and a collapse of the electric field within the amorphous chalcogenide layer.

FIG. 2 shows an example PCM cell 30 in the amorphous state. The size and shape of constriction of the phase change material 31 determines the resistance of the PCM cell 30. As shown in FIG. 2, the PCM cell 30 in the disordered amorphous state includes an amorphous layer 31A which limits current flowing through the PCM cell 30. In the amorphous state, the PCM cell 30 has a high level of resistivity (e.g., 1M ohm) and can be used to represent a binary 0.

FIG. 3 shows an example PCM cell 30 in the crystalline state. As shown in FIG. 3, the phase change material 31 of the PCM cell 30 in the ordered crystalline state is widened to allow more current flowing through the PCM cell 30. In the crystalline state, the PCM cell 30 has a low level of resistivity (e.g., 10K ohm) and can be used to represent a binary 1.

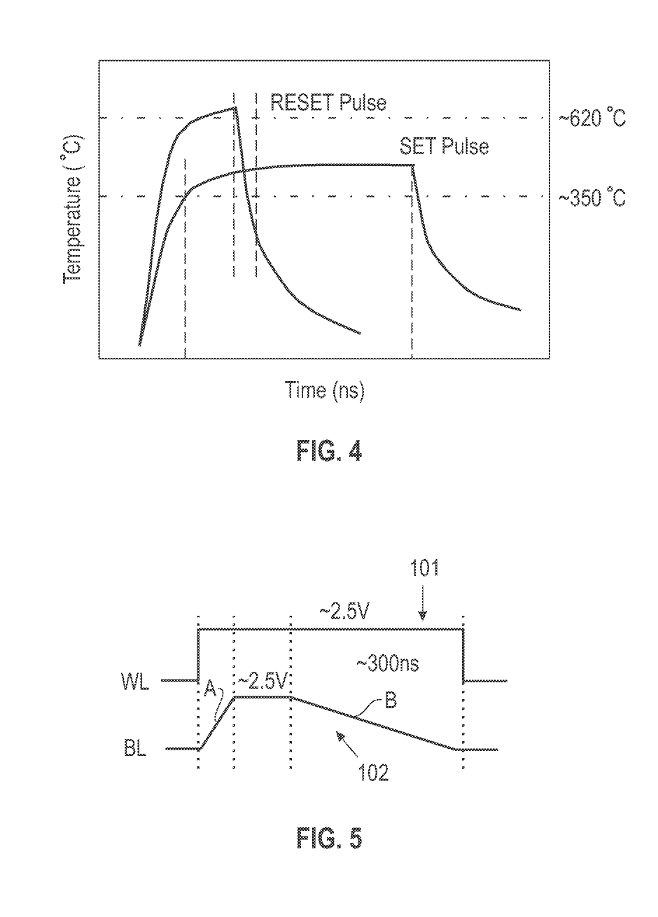

FIG. 4 shows a graph illustrating the temperature of a phase change material 31 of a PCM cell 30 with respect to time. When heat in the form of an electrical pulse (i.e., Joule heating) is applied to a PCM cell 30, the atomic order of the phase change material 31 is rearranged such that the phase change material 31 transitions between the crystalline state and the amorphous state. FIG. 4 illustrates a RESET pulse and a SET pulse.

The RESET pulse sets a logical 0 and forms an area of amorphous layer 31A (FIG. 2) on the phase change material 31 of the PCM cell 30. The RESET pulse raises the temperature of the phase change material 31 of the PCM cell 30 slightly above the melting point of the phase change material 31 (e.g., ˜620° C.). The phase change material 31 then cools rapidly to form the amorphous layer 31A. The duration of the RESET pulse is long enough to produce enough energy to melt the phase change material 31 of the PCM cell 30.

A SET pulse sets a logical 1 and re-crystallizes the amorphous layer 31A to the crystalline state 31B. The SET pulse raises the temperature of the phase change material of the PCM cell 30 slightly above the re-crystallization temperature, but below the melting point, of the phase change material 31 (e.g., ˜350° C.), and then allows the phase change material 31 a longer time to cool to allow the formation of crystalline grains 31B. The duration of the SET pulse is long enough to produce enough energy to re-crystallize the phase change material 31 of the PCM cell 30.

As shown in FIG. 4, the RESET pulse is higher, narrower, and steeper than the SET pulse. Further, the pulse width and fall time for the SET pulse is longer than the pulse width and fall time for the RESET pulse.

FIG. 5 shows waveforms of a word line and a bit line of a memory device 10 (FIG. 1) during a SET operation. The top trace 101 represents the electrical pulse applied to the word line 11 to activate the word line 11. To activate the word line 11, the voltage of the word line 11 is set to a high voltage equal to the positive supply voltage V_{DD} (e.g., ˜2.5 V). The duration of the electrical pulse is long enough to produce enough energy to anneal the phase change material 31 of the PCM cell 30 (e.g., ˜300 ns). When the word line 11 is activated, the access transistor 40 corresponding to the PCM cell 30 is turned on. The bottom trace 102 represents the voltage of the bit line 12 coupled to the PCM cell 30. When the access transistor 40 is turned on, a change in potential of the bit line 12 occurs. Specifically, the bit line 12 jumps to a positive potential as represented by the rising edge A of the bottom trace 102. By the end of the electrical pulse, the potential of the bit line 12 returns essentially to ground as represented by the falling edge B of the bottom trace 102.

Parallel writing to a memory array including multiple PCM cells connected to the same word line, however, is not reliable. For example, referring back to FIG. 1, the PCM cells 30 of the memory array 20 are initially in the RESET state. When the PCM cells 30 of the memory array 20 are programmed to the SET state, PCM1, the first PCM cell 30 of the memory array 20, undergoes threshold switching first. When PCM1 undergoes threshold switching, nearly all the current is consumed thereby making it difficult to maintain a large voltage difference across the word line 11. If a large voltage is not maintained, only PCM1 is programmed to the SET state. If a large voltage is maintained after PCM1 exceeds threshold Vt to allow other PCM cells 30 such as PCM2 to pass exceed threshold Vt, PCM1 will sink a large current and melt, resulting in a parasitic RESET. As such, the PCM cells 30 do not simultaneously transition to the SET state.

A PCM cell 30 is programmed by applying either voltage or current.

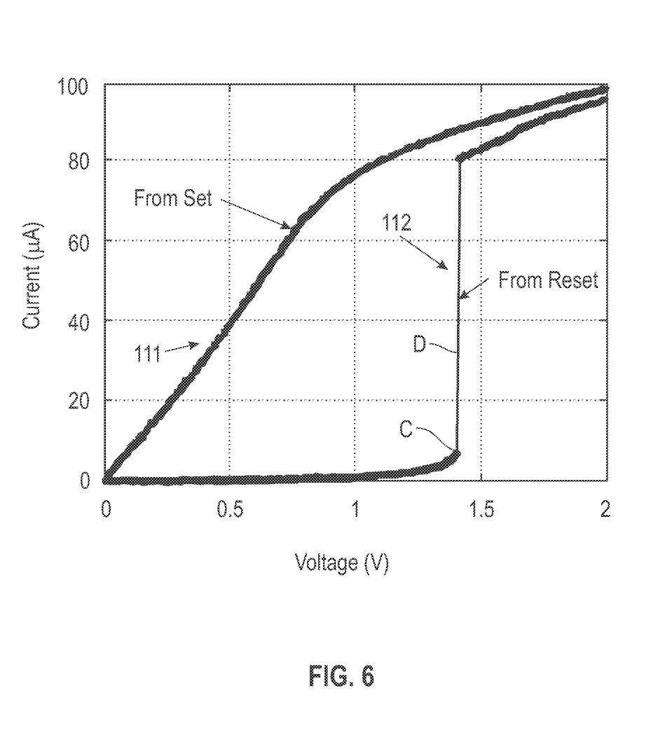

FIG. 6 shows current-voltage (I-V) curves for an example PCM cell 30 (FIG. 1) programmed by applying voltage. A first I-V curve 111 corresponds to programming the PCM cell 30 to switch from the SET state to the RESET state. The first I-V curve 111 shows an almost linear increase in current flowing through the resistor 50 (FIG. 2) of the PCM cell 30 with increasing voltage applied to the word line 11 (FIG. 1).

A second I-V curve 112 corresponds to programming the PCM cell 30 to switch from the RESET state to the SET state. Point C of the second I-V curve 112 represents when the voltage applied to the word line 11 exceeds the threshold voltage Vₜₕ. When the voltage threshold Vₜₕ is exceeded, the resistivity level of the PCM cell 30 drops considerably and the PCM cell 30 transitions to the SET state. As a result, a large overshoot in current flows through the resistor 50 of the PCM cell 30, as indicated by edge D of the second I-V curve 112. This large overshoot in current may melt the phase change material 31 of the PCM cell 30 and cause the PCM cell 30 to transition back to the RESET state. Thus, programming the PCM cell 30 to switch from the RESET state to the SET state by applying voltage to the word line 11 may result in a parasitic RESET.

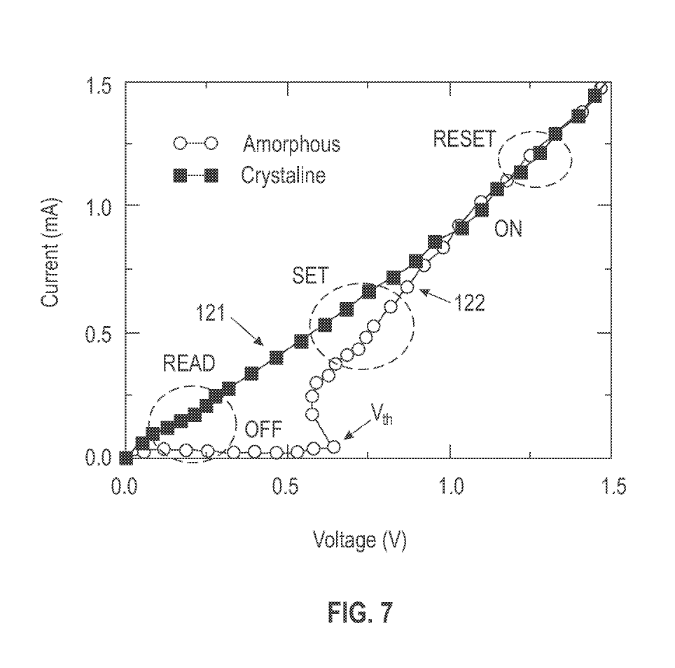

FIG. 7 shows current-voltage (I-V) curves for an example PCM cell 30 programmed by applying current. The first I-V curve 121 corresponds to the PCM cell 30 in the crystalline state. The first I-V curve 121 shows an almost linear increase in potential of the bit line 12 coupled to the PCM cell 30 with increasing current flowing through the resistor 50 of the PCM cell 30.

The second I-V curve 122 corresponds to the PCM cell 30 in the amorphous state. When the voltage exceeds the threshold voltage Vₜₕ, the PCM cell 30 becomes conductive. A small current is applied to anneal the amorphous layer of the phase change material 31 to the crystalline state.

The present invention discloses a programming circuit and a method to reliably parallel write to PCM cells in a memory array.

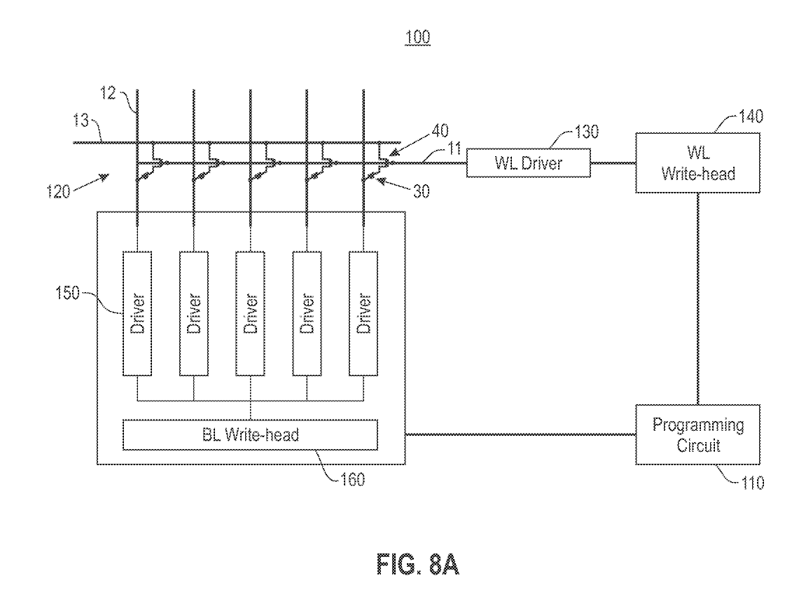

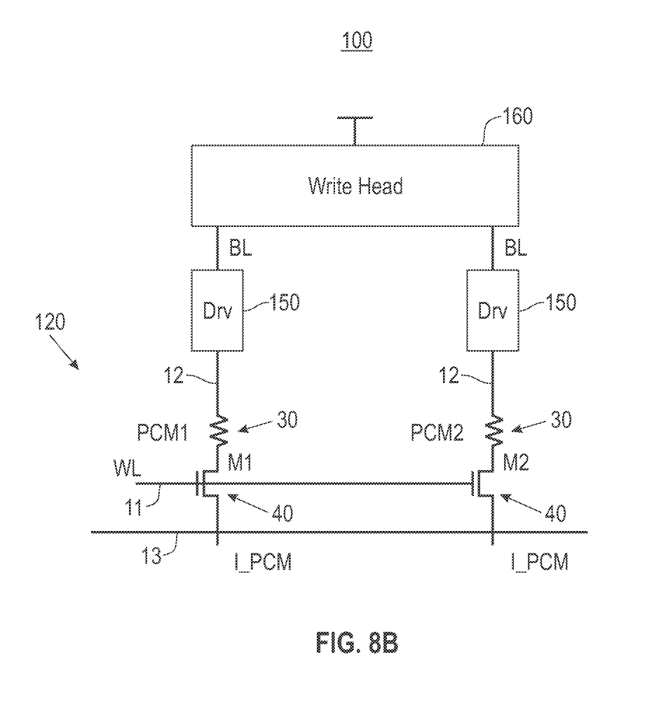

FIG. 8A shows a semiconductor memory device 100, in accordance with an embodiment of the invention. The memory device 100 comprises a memory array 120 including a plurality of PCM cells 30. The memory device 100 further comprises a select or word line (WL) 11, a plurality of sense or bit lines (BL) 12, and a reference voltage 13.

Each PCM cell 30 has a corresponding access transistor 40. The source 41 of each access transistor 40 is coupled to the reference voltage 13. The gate 42 of each access transistor 40 is coupled to the word line 11. Each PCM cell 30 is coupled to the drain 43 of its corresponding access transistor 40. Each PCM cell 30 is further coupled to a corresponding bit line 12. Each bit line 12 is coupled to a BL driver 150 configured to write data to, or read data from, the PCM cell 30 coupled to said bit line 12. The word line 11 is coupled to a WL driver 130 and a WL write head 140. The WL driver 130 and the WL write head 140 are configured to increase or decrease the voltage on the word line 11.

The memory device 100 further comprises a programming circuit 110 configured to program the PCM cells 30 of the memory device 100.

FIG. 8B shows an exploded view of a memory array 120 of a semiconductor memory device 100, in accordance with an embodiment of the invention. The PCM cells 30 of the memory array 120 include PCM1 and PCM2. The corresponding access transistor 40 of PCM1 is M1. The corresponding access transistor 40 of PCM2 is M2. Current flowing through each PCM cell 30 is labeled as I_PCM in FIG. 8B.

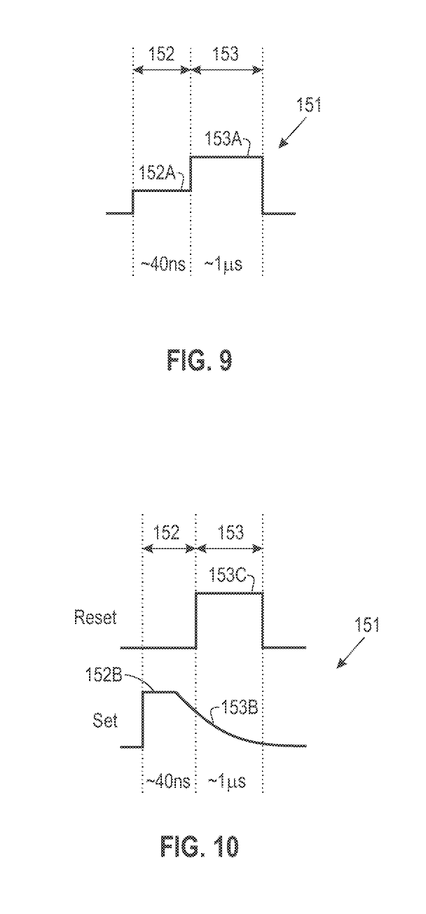

FIG. 9 shows a waveform of a word line 11 of a memory device 100 during a SET operation, in accordance with an embodiment of the invention. FIG. 10 shows waveforms of a bit line 12 of a memory device 100 during RESET and SET operations, in accordance with an embodiment of the invention. The programming circuit 110 is configured to reliably parallel write (i.e., parallel program) the PCM cells 30 of the memory device 100 by applying a complex two-stage waveform 151 at the word line 11 and bit lines 12 of the memory device 100. As shown in FIGS. 9-10, the waveform 151 includes a first stage 152 and a second stage 153.

The duration of the first stage 152 is in the range of 1 ns to 100 ns. For example, the duration of the first stage 152 may be ˜40 ns. The duration of the second stage 153 is in the range of 10 ns to 1000 ns. For example, the duration of the second stage 153 may be ˜1 μs. The example numerical ranges provided are approximate numerical ranges only, and the present invention is not limited to a duration within the numerical range.

During the first stage 152, current flowing through the PCM cells 30 of the memory device 100 is reliably limited, thereby preventing parasitic RESET as the PCM cells 30 undergo threshold switching. As shown in FIG. 9, the first stage 152 comprises a predetermined relatively low voltage 152A that is applied at the word line 11 of the memory device 100 to partially turn on the access transistors 40 of the memory device 100. As shown in FIG. 10, the first stage 152 further comprises a predetermined relatively high voltage 152B that is applied at the bit lines 12 of the memory device 100 to allow the PCM cells 30 of the memory device 100 to undergo threshold switching. The predetermined high voltage 152B may be equal to the positive supply voltage V_{DD}.

Partially turning on the access transistors 40 during the first stage 152 limits the amount of current flowing through the resistor 50 of each PCM cell 30. This enables the WL driver 130 to maintain the potential difference required for threshold switching and allow each PCM cell 30 to undergo threshold switching. Further, partially turning on the access transistors 40 prevents a large overshoot of current from flowing through the resistor 50 of each PCM cell 30 and melting the phase change material 31 of said PCM cell 30. Limiting the current during the first stage 152 prevents parasitic RESET.

During the second stage 153, the amorphous layer 31A (FIG. 2) of the phase change material 31 is reliably annealed to the crystalline state. As shown in FIG. 9, the second stage 153 comprises a predetermined relatively high voltage 153A that is applied at the word line 11 of the memory device 100 to fully turn on the access transistors 40 of the memory device 100. As shown in FIG. 10, the second stage 153 further comprises a predetermined voltage waveform 153B that is applied at the bit lines 12 of the memory to quench the amorphous layer 31A (FIG. 2) of the phase change material 31 of each PCM cell 30. The amplitude of the predetermined voltage 153B decreases with time.

Fully turning on the access transistors 40 during the second stage 153 allows enough current to flow through the resistor 50 of each PCM cell 30 to anneal the phase change material 31 of said PCM cell 30 to the crystalline state. The second stage 153 is voltage limiting in that the potential of the bit lines 12 gradually decreases with time. The rate of decreases of the amplitude of the predetermined voltage 153B may be calibrated so as to only partially anneal the amorphous layer 31A (FIG. 2) of each PCM cell 30 and program the resistivity level of said PCM cell to an intermediate value between the highest possible resistivity level and the lowest possible resistivity level.

The programming circuit 110 is also configured to parallel write the PCM cells 30 to the RESET state. To parallel write the PCM cells 30 to the RESET state, the predetermined relatively low voltage 152A and the predetermined relatively high voltage 153A are applied to the word line 11 of the memory device 100 during the first stage 152 and the second stage 153, respectively. Further, as shown in FIG. 10, a predetermined relatively high voltage 153C is applied at the bit lines 12 of the memory device 100 during the second stage 153.

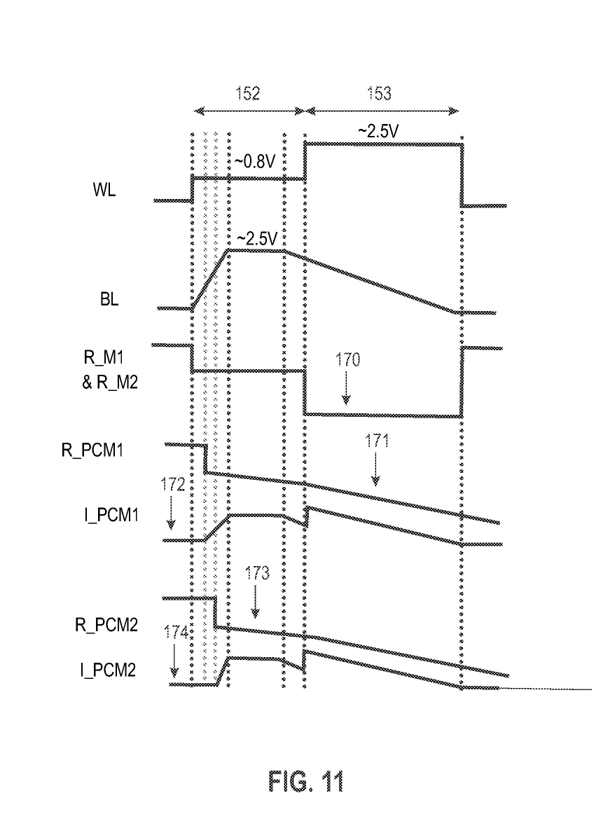

FIG. 11 shows example waveforms of a word line 11, a bit line 12, some PCM cells 30, and some access transistors 40 of a memory device 100 during a SET operation, in accordance with an embodiment of the invention. As described above, the programming circuit 110 reliably parallel writes the PCM cells 30 to the SET state by selectively applying the two-stage waveform 151 (FIGS. 9-10) to the word line 11 and the bit lines 12 of the memory device 100.

During the first stage 152, the predetermined relatively low voltage 152A and the predetermined relatively high voltage 152B are applied at the word line 11 and the bit lines 12 of the memory device 100, respectively. In one example implementation, the predetermined relatively low voltage 152A is about ˜0.8V, and the predetermined high voltage 152B is about ˜2.5V.

A waveform 170 (R_M1 & R_M2) represents the resistivity level of the access transistors M1 and M2. A waveform 171 (R_PCM1) represents the resistivity level of PCM1. A waveform 172 (I_PCM1) represents the amount of current flowing through PCM1. A waveform 173 (R_PCM2) represents the resistivity level of PCM2. A waveform 174 (I_PCM2) represents the amount of current flowing through PCM2.

The predetermined relatively low voltage 152A applied at the word line 11 partially turns on the access transistors 40, thereby limiting the amount of current flowing through the resistor 50 of each PCM cell 30 during the first stage 152. The predetermined relatively high voltage 152B applied at the bit lines 12 of the memory device 100 allows the PCM cells 30 of the memory device 100 to undergo threshold switching. For example, when PCM1 exceeds threshold Vₜₕ, the current flowing through PCM1 is limited by its corresponding access transistor M1 that has a high resistance during the first stage 152. This enables the WL driver 130 to maintain the potential difference required for threshold switching so that PCM2 can also undergo threshold switching.

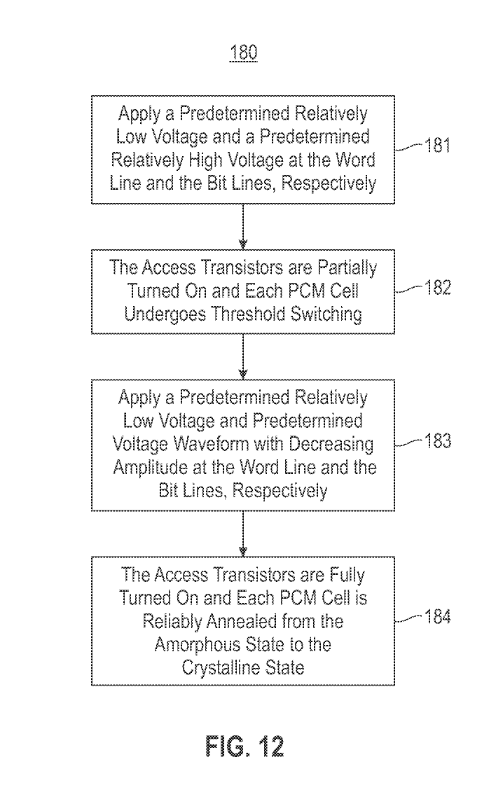

FIG. 12 is a flowchart of an example process 180 for reliably parallel writing PCM cells of a memory device to the SET state, in accordance with an embodiment of the invention. In process block 181, apply a predetermined relatively low voltage and a predetermined relatively high voltage at the word line and the bit lines of the memory device, respectively. In process block 182, the predetermined relatively low voltage applied at the word line partially turns on the access transistors of the memory device, and the predetermined relatively high voltage applied at the bit lines causes each PCM cells to undergo threshold switching. In process block 183, apply a predetermined relatively high voltage and a predetermined voltage waveform with decreasing amplitude at the word line and the bit lines of the memory device, respectively. In process block 184, the predetermined relatively high voltage applied at the word line fully turns on the access transistors of the memory device, and the predetermined voltage waveform with decreasing amplitude applied at the bit lines reliably anneals each PCM cell from the amorphous state to the crystalline state.

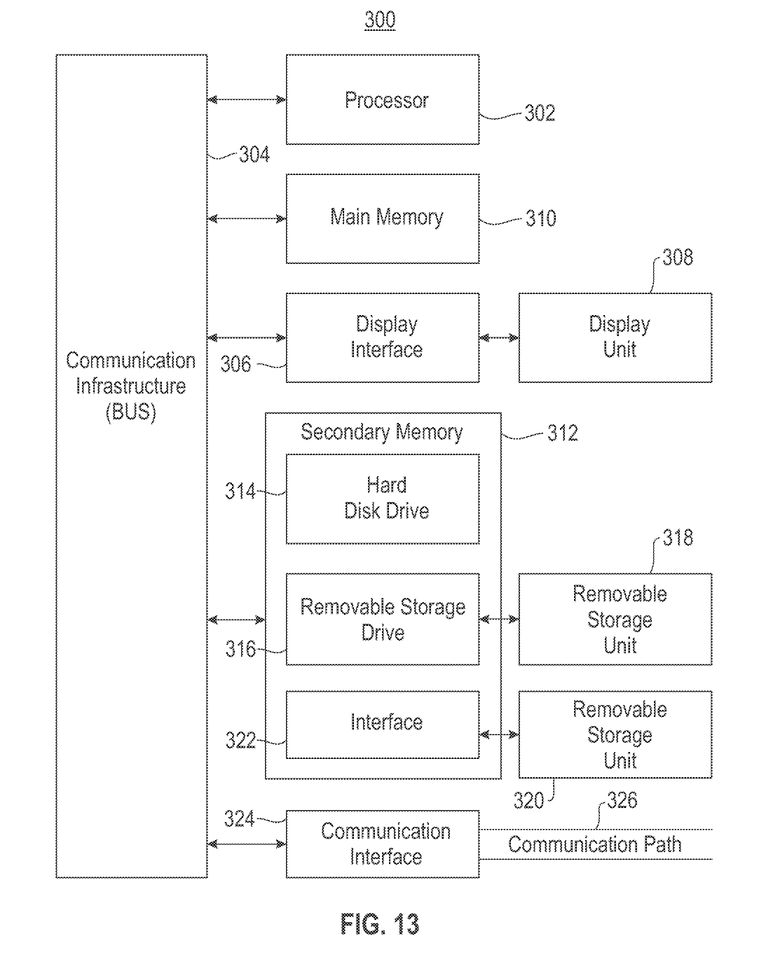

FIG. 13 is a high level block diagram showing an information processing system 300 useful for implementing one embodiment of the present invention. The computer system includes one or more processors, such as processor 302. The processor 302 is connected to a communication infrastructure 304 (e.g., a communications bus, cross-over bar, or network).

The computer system can include a display interface 306 that forwards graphics, text, and other data from the communication infrastructure 304 (or from a frame buffer not shown) for display on a display unit 308. The computer system also includes a main memory 310, preferably random access memory (RAM), and may also include a secondary memory 312. The secondary memory 312 may include, for example, a hard disk drive 314 and/or a removable storage drive 316, representing, for example, a floppy disk drive, a magnetic tape drive, or an optical disk drive. The removable storage drive 316 reads from and/or writes to a removable storage unit 318 in a manner well known to those having ordinary skill in the art. Removable storage unit 318 represents, for example, a floppy disk, a compact disc, a magnetic tape, or an optical disk, etc. which is read by and written to by removable storage drive 316. As will be appreciated, the removable storage unit 318 includes a computer readable medium having stored therein computer software and/or data.

In alternative embodiments, the secondary memory 312 may include other similar means for allowing computer programs or other instructions to be loaded into the computer system. Such means may include, for example, a removable storage unit 320 and an interface 322. Examples of such means may include a program package and package interface (such as that found in video game devices), a removable memory chip (such as an EPROM, or PROM) and associated socket, and other removable storage units 320 and interfaces 322, which allows software and data to be transferred from the removable storage unit 320 to the computer system.

The computer system may also include a communication interface 324. Communication interface 324 allows software and data to be transferred between the computer system and external devices. Examples of communication interface 324 may include a modem, a network interface (such as an Ethernet card), a communication port, or a PCMCIA slot and card, etc. Software and data transferred via communication interface 324 are in the form of signals which may be, for example, electronic, electromagnetic, optical, or other signals capable of being received by communication interface 324. These signals are provided to communication interface 324 via a communication path (i.e., channel) 326. This communication path 326 carries signals and may be implemented using wire or cable, fiber optics, a phone line, a cellular phone link, an RF link, and/or other communication channels.

In this document, the terms “computer program medium,” “computer usable medium,” and “computer readable medium” are used to generally refer to media such as main memory 310 and secondary memory 312, removable storage drive 316, and a hard disk installed in hard disk drive 314.

Computer programs (also called computer control logic) are stored in main memory 310 and/or secondary memory 312. Computer programs may also be received via communication interface 324. Such computer programs, when run, enable the computer system to perform the features of the present invention as discussed herein. In particular, the computer programs, when run, enable the processor 302 to perform the features of the computer system. Accordingly, such computer programs represent controllers of the computer system.

From the above description, it can be seen that the present invention provides a system, computer program product, and method for implementing the embodiments of the invention. The present invention further provides a non-transitory computer-useable storage medium for hierarchical routing and two-way information flow with structural plasticity in neural networks. The non-transitory computer-useable storage medium has a computer-readable program, wherein the program upon being processed on a computer causes the computer to implement the steps of the present invention according to the embodiments described herein. References in the claims to an element in the singular is not intended to mean “one and only” unless explicitly so stated, but rather “one or more.” All structural and functional equivalents to the elements of the above-described exemplary embodiment that are currently known or later come to be known to those of ordinary skill in the art are intended to be encompassed by the present claims. No claim element herein is to be construed under the provisions of 35 U.S.C. section 112, sixth paragraph, unless the element is expressly recited using the phrase “means for” or “step for.”

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A device, comprising:
a plurality of phase change memory cells, wherein each phase change memory cell is coupled to a corresponding transistor;
a word line, wherein each transistor is coupled to the word line;
a plurality of bit lines, wherein each bit line is coupled to a phase change memory cell of the device; and
a programming circuit configured to program at least one phase change memory cell to a SET state by selectively applying a two-stage waveform to the word line and the bit lines of the device.

2. The device of claim 1, wherein:
in a first stage, the waveform comprises:
a first predetermined low voltage; and
a first predetermined high voltage; and
in a second stage, the waveform comprises:
a second predetermined high voltage; and
a predetermined voltage with decreasing amplitude.

3. The device of claim 2, wherein the programming circuit:
applies the first predetermined low voltage at the word line during the first stage; and
applies the first predetermined high voltage at the bit lines during the first stage.

4. The device of claim 3, wherein:
for each phase change memory cell:
the first predetermined low voltage applied at the word line partially turns on the transistor of said phase change memory cell, such that current flowing through said phase change memory cell is limited; and
the first predetermined high voltage applied at the bit line of said phase change memory cell exceeds a threshold voltage of said phase change memory cell.

5. The device of claim 4, wherein the programming circuit:
applies the second predetermined high voltage at the word line during the second stage; and
applies the predetermined voltage with decreasing amplitude at the bit lines during the second stage.

6. The device of claim 5, wherein:
for each phase change memory cell:
the second predetermined high voltage applied at the word line fully turns on the transistor of said phase change memory cell; and
the first predetermined voltage with decreasing amplitude applied at the bit line of said phase change memory cell causes an amorphous volume in said phase change memory cell to anneal.

7. The device of claim 6, wherein:
for each phase change memory cell:
the amorphous volume in said phase change memory cell fully anneals to a crystalline state.

8. The device of claim 6, wherein:
for each phase change memory cell:
the first predetermined voltage with decreasing amplitude has a rate of decrease in amplitude that is calibrated to partially anneal the amorphous volume in said phase change memory cell to a level of resistivity that is lower than the amorphous volume and higher than a crystalline state of said phase change memory cell.

9. The device of claim 2, wherein:
the first stage has a duration in the range of 1 nanoseconds to 100 nanoseconds.

10. The device of claim 2, wherein:
the second stage has a duration in the range of 10 nanoseconds to 1000 nanoseconds.

11. A method for programming phase change memory cells of a memory device, the method comprising:
programming at least one phase change memory cell to a SET state by selectively applying a two-stage waveform to a word line and bit lines of the memory device;
wherein each phase change memory cell is coupled to a corresponding transistor;
wherein each transistor is coupled to the word line; and
wherein each bit line is coupled to a phase change memory cell of the memory device.

12. The method of claim 11, wherein:
in a first stage, the waveform comprises:
a first predetermined low voltage; and
a first predetermined high voltage; and
in a second stage, the waveform comprises:
a second predetermined high voltage; and
a predetermined voltage with decreasing amplitude.

13. The method of claim 12, wherein selectively applying the two-stage waveform to the word line and the bit lines of the device comprises:
applying the first predetermined low voltage at the word line during the first stage, wherein the first predetermined low voltage applied partially turns on the transistor of each phase change memory cell, such that current flowing through said phase change memory cell is limited; and
applying the first predetermined high voltage at the bit lines during the first stage, wherein the first predetermined high voltage applied exceeds a threshold voltage of each phase change memory cell.

14. The method of claim 13, wherein selectively applying the two-stage waveform to the word line and the bit lines of the device further comprises:
applying the second predetermined high voltage at the word line during the second stage, wherein the second predetermined high voltage applied fully turns on the transistor of each phase change memory cell; and
applying the predetermined voltage with decreasing amplitude at the bit lines during the second stage, wherein the predetermined voltage with decreasing amplitude applied anneals an amorphous volume in each phase change memory cell.

15. The method of claim 14, wherein the amorphous volume in each phase change memory cell fully anneals to a crystalline state.

16. The method of claim 15, wherein selectively applying the two-stage waveform to the word line and the bit lines of the device further comprises:
calibrating a rate of decrease in amplitude of the first predetermined voltage with decreasing amplitude, such that the amorphous volume in each phase change memory cell is partially annealed to a level of resistivity that is lower than the amorphous volume and higher than a crystalline state of said phase change memory cell.

17. The method of claim 12, wherein:
the first stage has a duration in the range of 1 nanoseconds to 100 nanoseconds.

18. The method of claim 12, wherein:
the second stage has a duration in the range of 10 nanoseconds to 1000 nanoseconds.

19. A non-transitory computer-useable storage medium for programming phase change memory cells of a memory device, wherein the memory device further comprises a word line and a plurality of bit lines, the computer-useable storage medium having a computer-readable program, wherein the program upon being processed on a computer causes the computer to implement the steps of:
programming at least one phase change memory cell to a SET state by selectively applying a two-stage waveform to the word line and the bit lines of the memory device, wherein each phase change memory cell is coupled to a corresponding transistor, wherein each transistor is coupled to the word line, and wherein each bit line is coupled to a phase change memory cell of the memory device;
applying a first predetermined low voltage at the word line during a first stage, wherein the first predetermined low voltage applied partially turns on the transistor of each phase change memory cell, such that current flowing through said phase change memory cell is limited;
applying a first predetermined high voltage at the bit lines during the first stage, wherein the first predetermined high voltage applied exceeds a threshold voltage of each phase change memory cell;
applying a second predetermined high voltage at the word line during the second stage, wherein the second predetermined high voltage applied fully turns on the transistor of each phase change memory cell; and
applying a predetermined voltage with decreasing amplitude at the bit lines during the second stage, wherein the predetermined voltage with decreasing amplitude applied anneals an amorphous volume in each phase change memory cell.

20. The non-transitory computer-useable storage medium of claim 19, wherein the computer-readable program further causes the computer to implement the steps of:
calibrating a rate of decrease in amplitude of the first predetermined voltage with decreasing amplitude, such that the amorphous volume in each phase change memory cell is partially annealed to a level of resistivity that is lower than the amorphous volume and higher than a crystalline state of said phase change memory cell.
